(19) United States
(12) Patent Application Publication
(10) Pub. No.: US 2011/0058393 A1
(43) Pub. Date: Mar. 10, 2011

(54) SWITCHING POWER SUPPLY DEVICE

(76) Inventor: Tohru SUZUKI, Niiza-shi (JP)

(21) Appl. No.: 12/870,960

(22) Filed: Aug. 30, 2010

(30) Foreign Application Priority Data
Sep. 4, 2009 (JP) 2009-204461

(51) Int. Cl. H02M 3/335; H03K 17/687

(52) U.S. Cl. 363/16; 327/434

(57) ABSTRACT

A switching power supply device that uses a SJ-MISFIT reduces a surge in voltage caused by the oscillation of drain current.

The switching power supply device of the present invention, which is switched by a switching element that is a MOSFET having a super junction structure, includes an oscillation reduction diode connected in anti-parallel to the switching element, wherein when a characteristic curve of output capacitance Coss of the switching element relative to a drain-to-source voltage VDS is approximated by a first line, second line and third line corresponding to lines A, B and C shown in FIG. 2, junction capacitance CD2 of the oscillation reduction diode at a point b where a characteristic curve of the junction capacitance CD2 of the oscillation reduction diode and the second line cross each other is 40% or more of the output capacitance Coss of the switching element at a point a where the first and second lines cross each other.

### BACKGROUND OF THE INVENTION

1. Field of the Invention

The present invention relates to a switching power supply device and particularly to a switching power supply device that uses a MOSFET of a super junction structure as a switching element.

2. Description of the Related Art

A switching power supply device that uses a MOSFET of a super junction structure (referred to as SJ-MOS, hereinafter) as a switching element has been developed in order to reduce losses in the switching element, achieve high efficiency and make the switching power supply device smaller. One example of SJ-MOS that is used as a switching element is a soft switching circuit disclosed in Jpn. Pat. Appln. Laid-Open Publication No. 2000-156978 (Patent Document 1). A high-voltage SJ-MOS can be realized without increasing on-resistance. Therefore, switching losses are small and it is possible to make the device more efficient and smaller.

### CITATION LIST

### Patent Document

[Patent Document 1] Jpn. Pat. Appln. Laid-Open Publication No. 2000-156978

However, as for the soft switching circuit disclosed in Patent Document 1 that uses the SJ-MOS, the SJ-MOS is supposed to be used in a range where the change of voltage-capacitance characteristic is moderate; the product used needs to withstand a higher voltage than is required in the actual operation. When the SJ-MOS capable of withstanding the level of voltage required in the actual operation is used, the oscillation of drain current occurs. The problem is that the noise resulting from the oscillating current has a bad effect on peripheral devices. Accordingly, a technique of reducing the noise caused by the oscillation of drain current is needed.

The phenomenon of oscillation in drain current that occurs when the SJ-MOS is used will be further described with reference to the accompanying drawings.

The capacitance (output capacitance Coss) between the drain and source of a MOSFET varies according to a drain-to-source voltage VDS to be applied. In particular, the SJ-MOS shows the following characteristic: as the applied voltage increases, the output capacitance Coss plunges from a certain level of voltage. In the example of the SJ-MOS of Patent Document 1, as shown in FIG. 3 that illustrates a SJ-MOS characteristic, the drain-to-source capacitance plunges at about 200 V. The characteristic of the output capacitance Coss is shown in FIG. 3 where the vertical axis represents the output capacitance Coss in logarithm while the horizontal axis represents the drain-to-source voltage VDS with a linear scale. Incidentally, FIG. 3 also shows a CONV. characteristic. The CONV. characteristic is the characteristic of output capacitance Coss of a typical MOSFET, not the SJ-MOS; the output capacitance Coss starts decreasing exponentially around 10 V.

According to the conventional technique disclosed in Patent Document 1, since the output capacitance Coss of the SJ-MOS is used as a capacitor Cs connected in parallel to the SJ-MOS, the SJ-MOS is designed to run in a range where the output capacitance Coss is large with 200 V or less. Therefore, according to the conventional technique disclosed in Patent Document 1, it is possible to keep the SJ-MOS from operating in a voltage range where the output capacitance Coss of the SJ-MOS plunges and therefore to prevent the drain current of SJ-MOS from oscillating fiercely. However, if the SJ-MOS is used in such a manner, the SJ-MOS used needs to withstand a higher voltage. However, the high-voltage product is expensive and the on-resistance is large, making it difficult to reduce costs.

Therefore, one way is to use the SJ-MOS capable of withstanding the level of voltage required in the actual operation. However, the voltage at which the output capacitance Coss of the SJ-MOS plunges tends to decrease as the level of voltage the SJ-MOS can withstand decreases. Accordingly, it is inevitable that the voltage at which the output capacitance Coss of the SJ-MOS plunges comes into the actual operating voltage range. When such a low-voltage SJ-MOS is used, the SJ-MOS passes through, in the process of switching operation, a point where the output capacitance Coss of the SJ-MOS plunges. At this time, the drain current of the SJ-MOS starts oscillating fiercely.

The following describes operational waveforms when the SJ-MOS is used whose voltage at which the output capacitance Coss of the SJ-MOS plunges is within the actual operating range.

FIG. 4 shows the configuration of a switching power supply device 10 according to a conventional technique that is used at the time. FIGS. 5A to 5C show the operational waveforms observed.

As shown in FIG. 4, a transformer T1 includes a primary winding N1 and a secondary winding N2. A switching element Q1, SJ-MOS, is connected in series to the primary winding N1 of the transformer T1. Between the drain and source terminals of the switching element Q1, a built-in diode DQ1, which is built into the switching element Q1, and a resonant capacitor C2 are connected in parallel. The gate terminal of the switching element Q1 is connected to a gate driving control circuit 2. The switching element Q1 is turned on or off on the basis of gate signals output from the gate driving control circuit 2.

The voltage that occurs at the secondary winding N2 of the transformer T1 is rectified and smoothed by a diode D1 and a smoothing capacitor C1 and then supplied to a load Ld as a direct-current voltage.

One terminal of the primary winding N1 of the transformer T1 is connected to the positive terminal of a direct-current power source Vin. The other terminal of the primary winding N1 is connected to the drain terminal of the switching element Q1. The source terminal of the switching element Q1 is connected to the negative terminal of the direct-current power source Vin. One terminal of the resonant capacitor C2 is connected to the drain terminal of the switching element Q1. The other terminal of the resonant capacitor C2 is connected to the source terminal of the switching element Q1.

One terminal of the secondary winding N2 of the transformer T1 is connected to the anode terminal of the diode D1. The cathode terminal of the diode D1 is connected to one terminal (positive side) of the smoothing capacitor C1 and one terminal of the load Ld. The diode D1 and the smoothing capacitor C1 make up a filter circuit. The other terminal of the secondary winding N2 of the transformer T1 is connected to the other terminal (negative side) of the smoothing capacitor C1 and the other terminal of the load Ld.

FIGS. 5A to 5C show waveforms observed when the switching power supply device having the above configuration is operated. The time scale is gradually expanded from FIG. 5A to FIG. 5C. FIGS. 5A to 5C show the gate-to-source voltage VGS, drain-to-source voltage VDS and drain current ID of the switching element Q1. More specifically, the drain current ID is a current flowing through a connection point where the drain terminal of the switching element Q1 and the anode terminal of the built-in diode DQ1 are connected (See ID indicated by arrow in FIG. 1). In particular, it is clear from the waveform of the drain current ID of FIG. 5C that oscillation occurs fiercely around where the drain current ID plunges to about 0 A.

The oscillation of the drain current ID turns out to be high-frequency noise to peripheral devices, causing harmful effects such as malfunction or noise.

### SUMMARY OF THE INVENTION

The object of the present invention is, in view of the above problems, to provide a switching power supply device able to reduce the oscillation of drain current.

According to the present invention, a switching power supply device switched by a switching element that is a MOSFET having a super junction structure includes an oscillation reduction diode connected in anti-parallel to the switching element, wherein when a characteristic curve of output capacitance of the switching element relative to a drain-to-source voltage is approximated by a first line, second line and third line corresponding to lines A, B and C shown in FIG. 2, junction capacitance of the oscillation reduction diode at a point where a junction capacitance characteristic curve of the oscillation reduction diode and the second line cross each other is 40% or more of the output capacitance of the switching element at a point where the first and second lines cross each other.

Moreover, according to the present invention, in the switching power supply device, the junction capacitance of the oscillation reduction diode at a time when the drain-to-source voltage is 0 V may be less than or equal to the output capacitance of the switching element at a time when the drain-to-source voltage is 0 V.

Furthermore, according to the present invention, in the switching power supply device, the switching element may include a built-in diode realized by parasitic capacitance, and the value of the output capacitance of the switching element may include the value of junction capacitance of the built-in diode.

Furthermore, according to the present invention, the switching power supply device may include: a primary winding of a transformer and the switching element that are connected in series between positive and negative terminals of a direct-current power source, and a resonant capacitor that is connected in parallel to the switching element; and a filter circuit including a diode and capacitor that are connected in series between one and the other terminals of a secondary winding of the transformer.

According to the present invention, it is possible to reduce the oscillation of drain current.

### BRIEF DESCRIPTION OF THE DRAWINGS

FIG. 1 is a diagram showing the circuit configuration of a switching power supply device according to the present invention;

FIG. 2 is a diagram showing an output capacitance characteristic of SJ-MOS and a junction capacitance characteristic of an oscillation reduction diode according of the present invention;

FIG. 3 is a diagram showing an output capacitance characteristic of SJ-MOS used for a technique of Patent Document 1 and an output capacitance characteristic of a conventional MOSFET;

FIG. 4 is a diagram showing the circuit configuration of a switching power supply device according to a conventional technique; and

FIGS. 5A to 5D show drawings showing operational waveforms of the switching power supply device of the conventional technique shown in FIG. 4 (FIGS. 5A to 5C) and operational waveforms of the switching power supply device of the present invention (FIG. 5D).

### DETAILED DESCRIPTION OF THE PREFERRED EMBODIMENTS

The following describes in detail an embodiment of the present invention with reference to the accompanying drawings.

According to the present embodiment, in a switching power supply device in which SJ-MOS (a MOSFET of a super junction structure) is used as a switching element Q1, an oscillation reduction diode is connected in parallel to a built-in diode of the switching element Q1 that is SJ-MOS: the junction capacitance of the oscillation reduction diode smoothly changes in a way that covers an abrupt change even when the abrupt change of an output capacitance Coss thereof occurs during the switching operation of the switching element Q1 that is SJ-MOS.

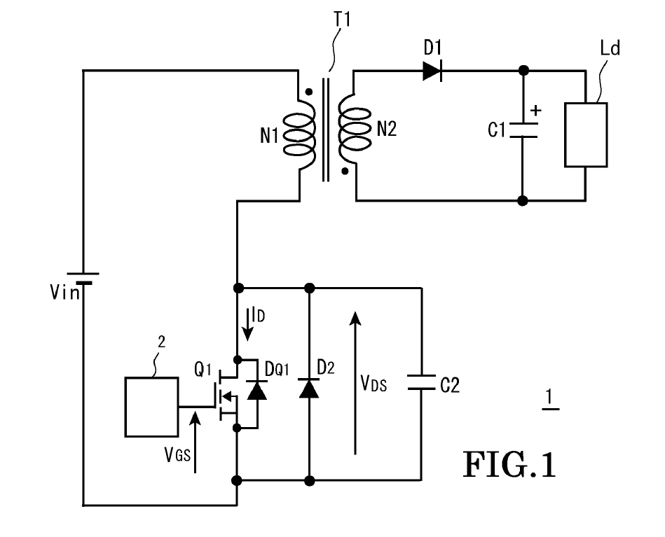

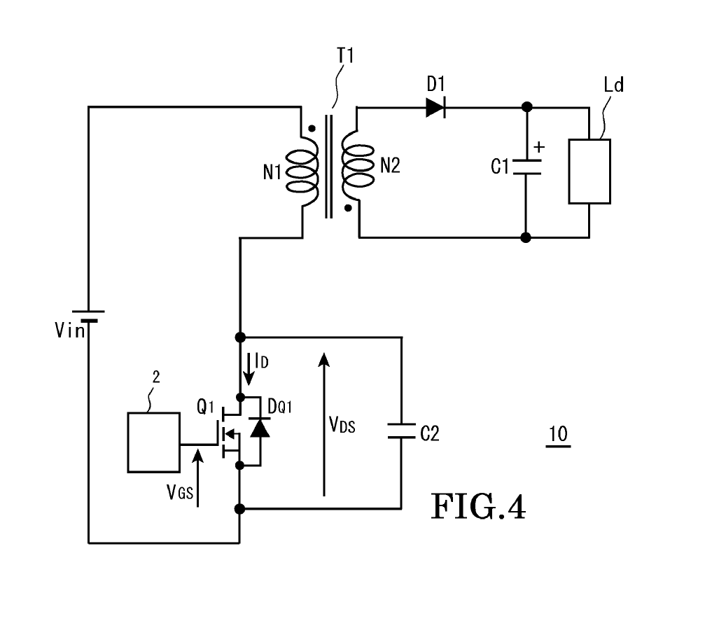

FIG. 1 is a diagram showing the circuit configuration of a switching power supply device 1 according to the embodiment of the present invention. The circuit configuration of the switching power supply device 1 and the circuit configuration of the switching power supply device 10 of FIG. 4 showing the conventional technique are different in that an oscillation reduction diode D2 is connected in anti-parallel to a switching element Q1 that is SJ-MOS. The same symbols as those of FIG. 4 represent the same components.

As shown in FIG. 1, a transformer T1 includes a primary winding N1 and a secondary winding N2. The switching element Q1, SJ-MOS, is connected in series to the primary winding N1 of the transformer T1. Between the drain and source terminals of the switching element Q1, a built-in diode DQ1, which is built into the switching element Q1, a resonant capacitor C2 and the oscillation reduction diode D2 are connected in parallel. The gate terminal of the switching element Q1 is connected to a gate driving control circuit 2. The switching element Q1 is turned on or off on the basis of gate signals output from the gate driving control circuit 2.

The voltage that occurs at the secondary winding N2 of the transformer T1 is rectified and smoothed by a diode D1 and a smoothing capacitor C1 and then supplied to a load Ld as a direct-current voltage.

One terminal of the primary winding N1 of the transformer T1 is connected to the positive terminal of a direct-current power source Vin. The other terminal of the primary winding N1 is connected to the drain terminal of the switching element Q1. The source terminal of the switching element Q1 is connected to the negative terminal of the direct-current power source Vin. One terminal of the resonant capacitor C2 and the cathode terminal of the oscillation reduction diode D2 are connected to the drain terminal of the switching element Q1. The other terminal of the resonant capacitor C2 and the anode terminal of the oscillation reduction diode D2 are connected to the source terminal of the switching element Q1.

One terminal of the secondary winding N2 of the transformer T1 is connected to the anode terminal of the diode D1. The cathode terminal of the diode D1 is connected to one terminal (positive side) of the smoothing capacitor C1 and one terminal of the load Ld. The diode D1 and the smoothing capacitor C1 make up a filter circuit. The other terminal of the secondary winding N2 of the transformer T1 is connected to the other terminal (negative side) of the smoothing capacitor C1 and the other terminal of the load Ld.

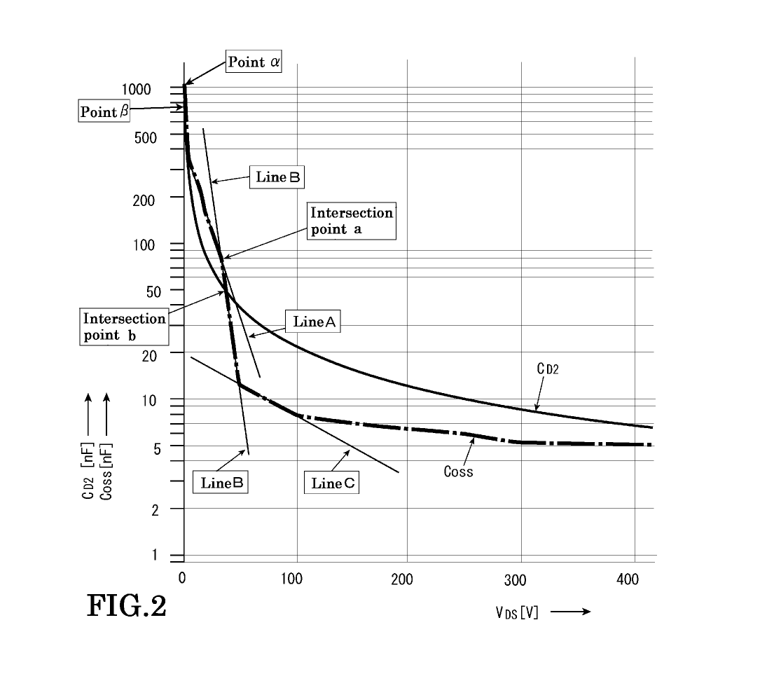

FIG. 2 is a graph showing the results of actual measurement of characteristics of the following capacitances relative to the drain-to-source voltage VDS: the output capacitance Coss of the SJ-MOS used for the switching element Q1; and the junction capacitance CD2 of the oscillation reduction diode D2 that is connected in anti-parallel to the SJ-MOS. In FIG. 2, the output capacitance Coss of the SJ-MOS is indicated by alternate long and short dash line, and the junction capacitance CD2 of the oscillation reduction diode D2 by solid line. As for the output capacitance characteristic of the SJ-MOS, the vertical axis represents the output capacitance Coss with a logarithmic scale; the horizontal axis represents the drain-to-source voltage VDS with a linear scale. As for the characteristic of the junction capacitance CD2 of the oscillation reduction diode D2, the vertical axis represents the junction capacitance CD2 with a logarithmic scale; the horizontal axis represents the drain-to-source voltage VDS with a linear scale. The drain-to-source voltage VDS can be regarded as the anode-to-cathode voltage of the oscillation reduction diode D2. On the graph, the value of the output capacitance Coss of the SJ-MOS is a combination of the output capacitance the SJ-MOS has and the junction capacitance of the built-in diode DQ1 built into the SJ-MOS. Incidentally, the capacitances are measured after the gate and source terminals are short-circuited with a measurement frequency of 1 MHz.

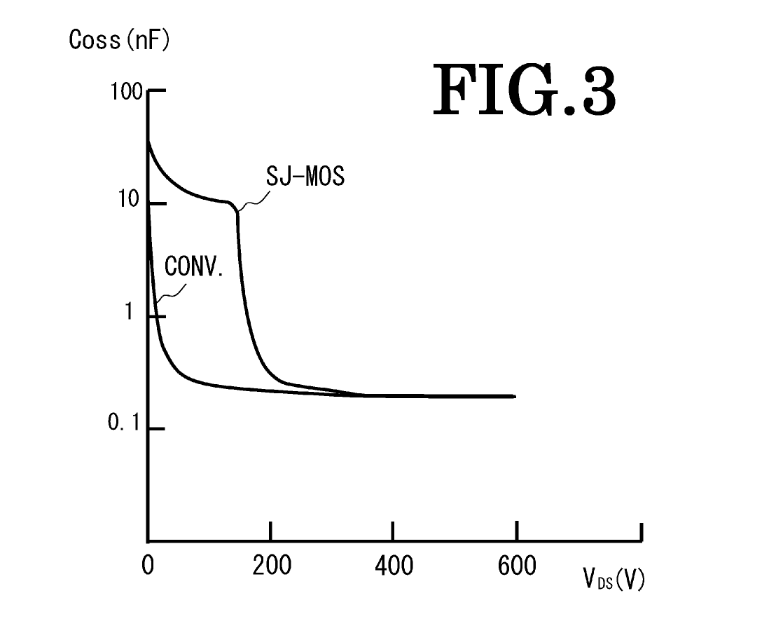

In FIG. 2, a similar trend appears to the characteristic curve of the output capacitance Coss of the SJ-MOS as shown in FIG. 3 (See Patent Document 1). The characteristic curve of the actually measured output capacitance Coss of FIG. 2 has areas approximated by lines A, B and C as illustrated in the diagram. The area approximated by the line A corresponds to an area where the drain-to-source voltage VDS is about 200 V or less in the characteristic diagram of FIG. 3 or to an area where the drain-to-source voltage VDS is about 33 V or less according to the results of actual measurement of the present embodiment. The change of the output capacitance Coss in the area is relatively gentle compared with that in the area approximated by the line B described below.

The area approximated by the line B corresponds to an area where the drain-to-source voltage is around 200 V and the output capacitance Coss plunges in the characteristic diagram of FIG. 3 or to an area where the drain-to-source voltage is about 33 V to 47 V according to the results of actual measurement of the present embodiment. The change of the output capacitance Coss in the area is largest.

It is unclear which area in the characteristic diagram of FIG. 3 corresponds to the area approximated by the line C. However, the area approximated by the line C is an area where the output capacitance Coss decreases relatively gently compared with the other areas or an area where the drain-to-source voltage is about 47 V to 100 V according to the results of actual measurement of the present embodiment.

Incidentally, it should be understood by those skilled in the art that the actual measurement values described above are one example and vary according to the elements. It should be also understood by those skilled in the art that the drain-to-source voltage at which the output capacitance Coss plunges varies according to the specifications of withstanding voltage of the elements.

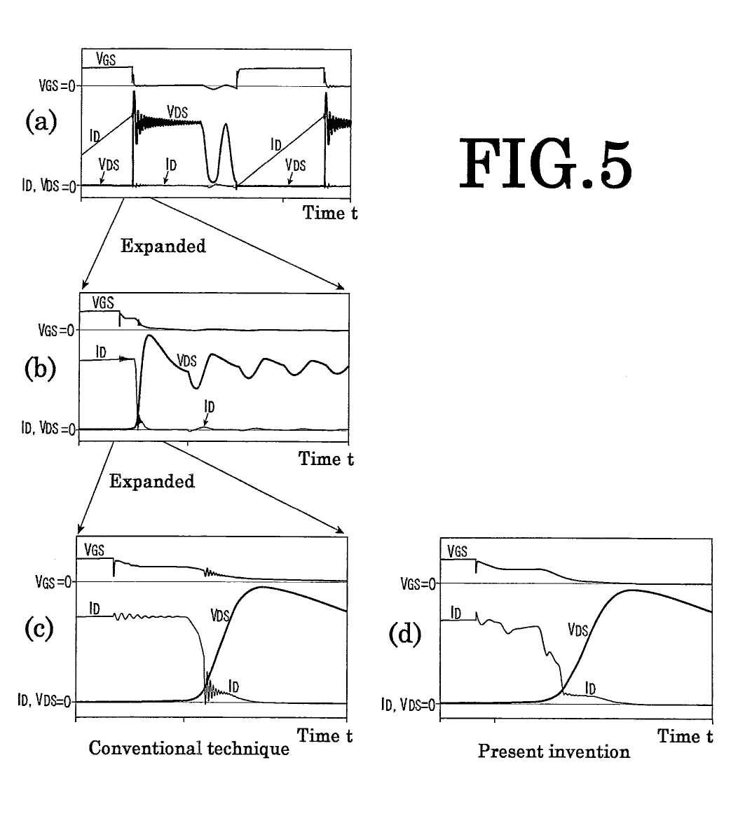

The characteristic of the junction capacitance CD2 of the oscillation reduction diode D2 changes exponentially and smoothly relative to the characteristic curve of the output capacitance Coss of the SJ-MOS (switching element Q1). When the characteristic of the output capacitance Coss of the SJ-MOS (switching element Q1) is such an exponential, smooth change, there is no abrupt change in the characteristic of a resonant circuit that is made up of the output capacitance Coss of the SJ-MOS (switching element Q1), the capacitor C2 and the wiring inductance therebetween, thereby making it difficult for the oscillation of the drain current ID, like the one shown in FIG. 5C, to occur.

Therefore, according to the present invention, the characteristic of the junction capacitance CD2 of the oscillation reduction diode D2 is set so that the characteristic of the output capacitance Coss of the SJ-MOS and the junction capacitance CD2 of the oscillation reduction diode D2 combined is brought closer to the characteristic of such an exponential, smooth change. More specifically, the inventor found that there is almost no oscillation of the drain current ID when the capacitance at a point b where the line B and the characteristic curve of the junction capacitance CD2 cross each other is set at about 40% or more of the capacitance at a point a where the lines A and B cross each other. Therefore, it is desirable that the characteristic of the junction capacitance CD2 of the oscillation reduction diode D2 be set so that the capacitance at the point b where the line B and the characteristic curve of the junction capacitance CD2 cross each other is set at about 40% or more of the capacitance at the point a where the lines A and B cross each other.

In addition, it is desirable that the value of the capacitance (indicated by point β) for the 0 V drain-to-source voltage VDS of the characteristic curve of the junction capacitance CD2 be less than or equal to the value of the capacitance (indicated by point α) for the 0 V drain-to-source voltage VDS of the characteristic curve of the output capacitance Coss. Accordingly, the value of the characteristic of the output capacitance Coss of the SJ-MOS to which the junction capacitance CD2 of the oscillation reduction diode D2 is added is approximate to the value of the characteristic of the output capacitance Coss of the SJ-MOS, thereby preventing the switching operation of the SJ-MOS from being delayed significantly.

Incidentally, the purpose of connecting the oscillation reduction diode D2 is to bring the characteristic of the output capacitance Coss of the SJ-MOS closer to the characteristic of an exponential, smooth change. When the oscillation reduction diode D2 is connected in parallel with the built-in diode DQ1, a current can flow through the oscillation reduction diode D2 or built-in diode DQ1.

FIG. 5D shows waveforms at a time when the switching power supply device 1 having the above configuration is running. FIG. 5D shows the gate-to-source voltage VGS of the switching element Q1, the drain-to-source voltage VDS, and the drain current ID. It is confirmed from the waveform of the drain current ID of FIG. 5D that a fierce oscillation, like the one shown in FIG. 5C of the conventional technique, does not occur around an area where the drain current ID plunges to about 0 V. That is, it is possible for the switching power supply device 1 to reduce the oscillation of the drain current.

The above has described in detail the present invention with reference to the embodiment. Needless to say, the present invention is not limited to the above embodiment; modifications may be made without departing from the scope of the present invention.

For example, the switching power supply device 1 shown in FIG. 1 is described as a switching power supply device to which the present invention is applied. However, the present invention is not limited to the circuit configuration. As the switching power supply device, a resonant switching power supply device or any other type can be applied.

What is claimed is:

1. A switching power supply device switched by a switching element that is a MOSFET having a super junction structure, comprising
an oscillation reduction diode connected in anti-parallel to the switching element, wherein
when a characteristic curve of output capacitance of the switching element relative to a drain-to-source voltage is approximated by a first line, second line and third line corresponding to lines A, B and C shown in FIG. 2, junction capacitance of the oscillation reduction diode at a point where a junction capacitance characteristic curve of the oscillation reduction diode and the second line cross each other is 40% or more of the output capacitance of the switching element at a point where the first and second lines cross each other.

2. The switching power supply device according to claim 1, wherein
the junction capacitance of the oscillation reduction diode at a time when the drain-to-source voltage is 0 V is less than or equal to the output capacitance of the switching element at a time when the drain-to-source voltage is 0 V.

3. The switching power supply device according to claim 1, wherein
the switching element includes a built-in diode realized by parasitic capacitance, and the value of the output capacitance of the switching element includes the value of junction capacitance of the built-in diode.

4. The switching power supply device according to claim 1, comprising:
a primary winding of a transformer and the switching element that are connected in series between positive and negative terminals of a direct-current power source, and a resonant capacitor that is connected in parallel to the switching element; and
a filter circuit including a diode and capacitor that are connected in series between one and the other terminals of a secondary winding of the transformer.
